(19) United States
(12) Patent Application Publication
(10) Pub. No.: US 2015/0367253 A1
(43) Pub. Date: Dec. 24, 2015

(54) PHOTOLUMINESCENT THIN-LAYER CHROMATOGRAPHY PLATE AND METHODS FOR MAKING SAME

(71) Applicants: US SYNTHETIC CORPORATION, OREM, UT (US); BRIGHAM YOUNG UNIVERSITY, PROVO, UT (US)

(72) Inventors: Supriya Kanyal, Provo, UT (US); Cody Vic Cushman, Springville, UT (US); Matthew R. Linford, Orem, UT (US); David Scott Jensen, Spanish Fork, UT (US)

(21) Appl. No.: 14/741,376

(22) Filed: Jun. 16, 2015

Related U.S. Application Data
(60) Provisional application No. 62/016,381, filed on Jun. 24, 2014.

(51) Int. Cl. B01D 15/38; C23C 16/455; C23C 16/34; B01D 15/20

(52) U.S. Cl. CPC B01D 15/3857; B01D 15/206; C23C 16/45525; C23C 16/345

(57) ABSTRACT

In an embodiment, a method for manufacturing a chromatography apparatus such as a thin layer chromatography (“TLC”) plate is disclosed. The method includes forming a layer of elongated nanostructures (e.g., carbon nanotubes), and at least partially coating the oxidized elongated nanostructures with a coating. The coating includes a stationary phase and/or precursor of a stationary phase and at least one photoluminescent material for use in chromatography. Embodiments for TLC plates and related methods are also disclosed.

### CROSS-REFERENCE TO RELATED APPLICATIONS

This application claims priority to U.S. Provisional Application No. 62/016,381 filed on 24 Jun. 2014, the disclosure of which is incorporated herein, in its entirety, by this reference.

### BACKGROUND

Chromatography and solid-phase extraction (“SPE”) are commonly-used separation techniques employed in a variety of analytical chemistry and biochemistry environments. Chromatography and SPE are often used for separation, extraction, and analysis of various constituents, or fractions, of a sample of interest. Chromatography and SPE may also be used for the preparation, purification, concentration, and clean-up of samples.

Chromatography and SPE relate to any of a variety of techniques used to separate complex mixtures based on differential affinities of components of a sample carried by a mobile phase with which the sample flows, and a stationary phase through which the sample passes. Typically, chromatography and SPE involve the use of a stationary phase that includes an adsorbent packed into a cartridge, column, or disposed as a thin layer on a plate. Thin-layer chromatography (“TLC”) employs a stationary phase that is spread in a thin layer on a carrier or substrate plate. A commonly-used stationary phase includes a silica-gel-based sorbent material.

Mobile phases are often solvent-based liquids, although gas chromatography typically employs a gaseous mobile phase. Liquid mobile phases may vary significantly in their compositions depending on various characteristics of the sample being analyzed and on the various components sought to be extracted and/or analyzed in the sample. For example, liquid mobile phases may vary significantly in pH and solvent properties. Additionally, liquid mobile phases may vary in their compositions depending on the characteristics of the stationary phase that is being employed. Often, several different mobile phases are employed during a given chromatography or SPE procedure. For example, gradient elution may be performed in which the mobile phase composition is varied with time or by sequence.

A typical TLC plate is prepared by mixing an adsorbent (which acts as the stationary phase) with a small amount of an inert binder and water. The mixture may be spread as relatively viscous slurry onto a carrier sheet. The resulting stationary phase is bound in place to the carrier sheet or other substrate by the binder. The presence of the binder can lead to secondary interactions with the mobile phase, as well as a decrease in separation efficiency.

### SUMMARY

Embodiments of the invention relate to chromatography apparatuses such as TLC plates, methods of using such TLC plates in chromatography, and related methods of manufacture in which a plurality of elongated stationary phase structures including at least one photoluminescent material (e.g., a fluorescent material and/or a phosphorescent material) are formed and affixed to a substrate. The use of at least one photoluminescent material in stationary phase structures of a TLC plate may provide excellent contrast between the TLC plate and analytes thereon under ultraviolet (“UV”) light.

In an embodiment, a method of manufacturing a chromatography apparatus (e.g., a TLC plate) is disclosed. The method includes forming a catalyst layer on a substrate. A layer of elongated nanostructures (e.g., carbon nanotubes) is then formed on the catalyst layer. A coating may be applied to the elongated nanostructures. The coating includes at least one of a stationary phase or a precursor of a stationary phase and at least one photoluminescent material. The coating is formed by depositing at least one photoluminescent material (e.g., a fluorescent material such as zinc oxide) on the elongated nanostructures, and depositing one or more silicon-containing materials on the elongated nanostructures having the at least one photoluminescent material thereon.

In an embodiment, a chromatography apparatus includes a substrate and a catalyst material on the substrate. A plurality of stationary phase structures are formed over the substrate. At least some of the plurality of stationary phase structures include at least one photoluminescent material layer (e.g., a fluorescent material such as zinc oxide) and at least one stationary phase material including at least one of silicon dioxide or silicon nitride.

Features from any of the disclosed embodiments may be used in combination with one another, without limitation. In addition, other features and advantages of the present disclosure will become apparent to those of ordinary skill in the art through consideration of the following detailed description and the accompanying drawings.

### BRIEF DESCRIPTION OF THE DRAWINGS

The drawings illustrate several embodiments of the invention, wherein identical reference numerals refer to identical or similar elements or features in different views or embodiments shown in the drawings.

FIG. 1 is a schematic top plan view of an embodiment of a TLC plate intermediate structure including a substrate and a catalyst layer disposed over the substrate, with the catalyst layer exhibiting a zigzag pattern.

FIG. 2 is a schematic top plan view of another embodiment of a TLC plate intermediate structure similar to FIG. 1, but the catalyst layer exhibits an alternative zigzag pattern.

FIG. 3 is a schematic top plan view of another embodiment of a TLC plate intermediate structure similar to FIG. 1, but the catalyst layer exhibits a substantially parallel spacing pattern.

FIG. 4 is a schematic top plan view of another embodiment of a TLC plate intermediate structure similar to FIG. 3, but the catalyst layer exhibits another substantially parallel spacing pattern.

FIG. 5 is a schematic top plan view of another embodiment of a TLC plate intermediate structure similar to FIG. 1, but the catalyst layer exhibits a diamond-shaped pattern.

FIG. 6 is a schematic top plan view of another embodiment of a TLC plate intermediate structure similar to FIG. 5, but the catalyst layer exhibits another diamond-shaped pattern.

FIG. 7 is a schematic top plan view of another embodiment of a TLC plate intermediate structure similar to FIG. 1, but the catalyst layer exhibits a honeycomb-like pattern.

FIG. 8 is a schematic top plan view of another embodiment of a TLC plate intermediate structure similar to FIG. 7, but the catalyst layer exhibits another honeycomb-like pattern.

FIG. 9 is a schematic top plan view of another embodiment of a TLC plate intermediate structure similar to FIG. 7, but the catalyst layer exhibits another honeycomb-like pattern.

FIG. 10A is a cross-sectional view of the TLC plate intermediate structure of FIG. 1.

FIG. 10B is a cross-sectional view of the TLC plate intermediate structure of FIG. 10A with CNTs grown on the catalyst layer.

FIG. 10C is a close-up transverse cross-sectional view of an embodiment in which the CNT includes one or more priming layer(s), where the CNTs, priming layer(s) or both have been subjected to oxidation.

FIG. 10D is a cross-sectional view of the TLC plate intermediate structure of FIG. 10B once the oxidized CNTs have been at least partially coated by a stationary phase coating.

FIG. 10DD is a close-up transverse cross-sectional view of one of the coated CNTs of FIG. 10D.

FIG. 10E is a cross-sectional view of the TLC plate intermediate structure of FIG. 10D once the CNTs have been burned off, leaving behind the stationary phase structures.

FIG. 10EE is a close-up transverse cross-sectional view similar to FIG. 10DD, but once the CNTs have been burned off.

FIG. 11A is a schematic top plan view of a TLC plate manufactured from a TLC plate intermediate structure similar to that of FIG. 1.

FIG. 11B is a close-up top plan view of the TLC plate intermediate structure of FIG. 11A showing several of the high aspect ratio deposited stationary phase structures disposed on the TLC plate substrate.

FIG. 12 is a schematic view illustrating various flow channel width, channel length, and hedge width configurations for a zig-zag pattern according to an embodiment.

FIG. 13 is a schematic view of a method of making a fluorescent TLC plate according to an embodiment.

FIGS. 14A and 14B are Transmission Electron Microscope images of coated CNTs according to an embodiment.

FIGS. 15A and 15B are photographs under ultraviolet (“UV”) light of TLC plates made according to different embodiments.

FIG. 16 is a photograph under UV light of a TLC plate made according to an embodiment.

FIG. 17 is a photograph under UV light of a TLC plate made according to an embodiment and having analytes thereon after a chemical separation according to an embodiment.

### DETAILED DESCRIPTION

Embodiments of the invention are directed to TLC plates and related methods of manufacture and use. The disclosed TLC plates may include a plurality of elongated stationary phase structures affixed to a substrate exhibiting a suitable photoluminescence for chromatography applications. The incorporation of a photoluminescent material (e.g., a fluorescent material and/or a phosphorescent material) in a TLC plate may provide higher contrast for analytes on such TLC plate as compared to a TLC plate without a photoluminescent material.

In various embodiments, a TLC plate may be manufactured by forming a layer of elongated nanostructures on a substrate; optionally, oxidizing (e.g., ozone treating) the elongated nanostructures; and then at least partially coating the elongated nanostructures with a coating that includes a stationary phase and/or a precursor to the stationary phase for use in chromatography, at least one fluorescent material; and optionally, a protective layer. While the description hereinbelow uses carbon nanotubes (“CNT”) as an example of a suitable elongated nanostructure, other elongated nanostructures may be used, such as semiconductor nanowires with or without a porous coating, polymeric nanowires which may be made by electrospinning, metallic nanowires with or without a porous coating, nanopillars formed by nanoimprint lithography, combinations of the foregoing, or any other suitable nanostructure.

While priming of the CNTs with a thin priming layer (e.g., such as amorphous carbon, alumina, ozone etc.) may not be necessary, in some embodiments, the CNTs may optionally be primed before deposition of the stationary phase or precursor thereof, if desired. In such cases, the elongated nanostructures, the one or more adhesion priming layers, or both may oxidized (e.g., ozone treated) to provide a surface enriched in oxygen moieties.

The CNTs may generally be vertically aligned relative to one another, although some contact and/or at least partial intertwining of adjacent CNTs may occur, which may provide increased mechanical stability to individual “hedge” portions of a given pattern, or to the overall CNT forest. The CNTs may be optionally primed via oxidization to form a surface enriched in oxygen moieties for promoting subsequent deposition of the stationary phase coating or precursor thereof. The surface may be coated with a stationary phase that has a thickness less than the CNT hedge spacing (i.e., leaving a “flow channel”), which results in a porous medium through which separation by means of chromatography may occur. The resulting pattern may thus include a series of hedges separated by flow channels. The CNT forest is used as a framework on which the stationary phase may be coated and/or formed, resulting in a finished structure that is generally free of any binder for binding the stationary phase to the substrate. In some embodiments, CNTs may be directly coated with silicon nitride or other materials as explained below.

The substrate may include a base, a backing layer (e.g., diffusion barrier) disposed on the base, and a catalyst layer disposed on the backing layer that is used to catalyze growth of CNTs over the substrate. Generally, the catalyst layer may be deposited onto the backing layer by any suitable technique. For example, placement of the catalyst layer may be accomplished using a photolithography process, such as masking the catalyst layer and etching to remove regions of the catalyst layer exposed through the mask. Such photolithography processes may be used to produce a catalyst layer having a selected non-linear (e.g., zigzag) pattern. In embodiments, a layer of photoresist (e.g., AZ3312) may be coated on the catalyst layer, the photoresist may be developed (i.e., etched or photo-etched) using UV light and then the photoresist may be washed to reveal the pattern created with the UV light. The photoresist may be removed by exposing the photoresist to a suitable stripping or removal agent (e.g., N-methylpyrollidone). The catalyst layer may then be etched through the patterned photoresist layer to define a corresponding pattern in the catalyst layer. Alternatively, the base may be coated with a layer of photoresist, and the photoresist may be developed by exposure to UV light. Depending on the polarity of the photoresist, the exposed or unexposed photoresist may then be removed by exposure to an appropriate developing solvent. The resulting patterned base can then be coated with a backing layer (e.g., alumina), followed by a catalyst (e.g., iron). The remaining photoresist is then removed, which removes the backing layer and catalyst from the unpatterned parts of the base. Other patterning processes such as shadow masking with a stencil mask during catalyst deposition, printing, wet-etching, dry-etching, or Reactive-Ion Etching (“RIE”) process may also be used. In another embodiment, the catalyst layer may be applied so as to coat substantially the entire substrate.

The catalyst layer may comprise any suitable material that catalyzes growth of CNTs under suitable growing conditions (e.g., heating and exposure to a process gas such as H₂ and a carbon-containing gas such as C₂H₄). Various transition metals may be suitable for use as a catalyst layer. Suitable metals include, but are not limited to iron, nickel, copper, cobalt, alloys of the forgoing metals, and combinations thereof.

The backing layer of the substrate provides support for the structures of the TLC plate. For example, the backing layer provides a support on which the catalyst layer may be deposited, and may also function as a diffusion barrier to help prevent a chemical reaction between the catalyst layer and the base (e.g., poisoning of iron catalyst by silicon from the base). Examples of backing layer materials may include, but are not limited to, silicon, silica (e.g., fused silica), alumina, a low-expansion high-temperature borosilicate glass (e.g., Pyrex 7740 and/or Schott Borofloat glass), steel (e.g., stainless steel), nickel, or any other high-temperature glass or other suitable material. In embodiments where the backing layer comprises a material other than alumina, the backing layer may be prepared for CNT growth by application of a thin layer of alumina over the non-alumina backing layer. The alumina layer may have a thickness between about 5 nm and about 100 nm, more specifically between about 10 nm and about 50 nm, and most specifically between about 20 nm and about 40 nm (e.g., about 30 nm).

A catalyst layer (e.g., iron) may be applied over the backing layer. The catalyst layer may have a thickness between about 0.1 nm and about 15 nm, more particularly between about 0.5 nm and about 10 nm, and even more particularly between about 0.5 nm and about 8 nm (e.g., about 2 to about 7 nm). For example, the catalyst layer may have a thickness of about 0.5 nm, about 1 nm, about 2 nm, about 3 nm, about 4 nm, about 5 nm, about 6 nm, about 7 nm, about 8 nm, about 9 nm, about 10 nm, about 11 nm, about 12 nm, about 13 nm, about 14 nm, or about 15 nm. Although specific catalyst layer thicknesses are disclosed above, the inventors have further found that varying the thickness of the catalyst layer affects some or each of the diameter, density, or height of CNTs grown under otherwise identical conditions. As such, according to an embodiment, the catalyst layer thickness may be altered to change one or more of diameter, density, or height of the grown CNTs.

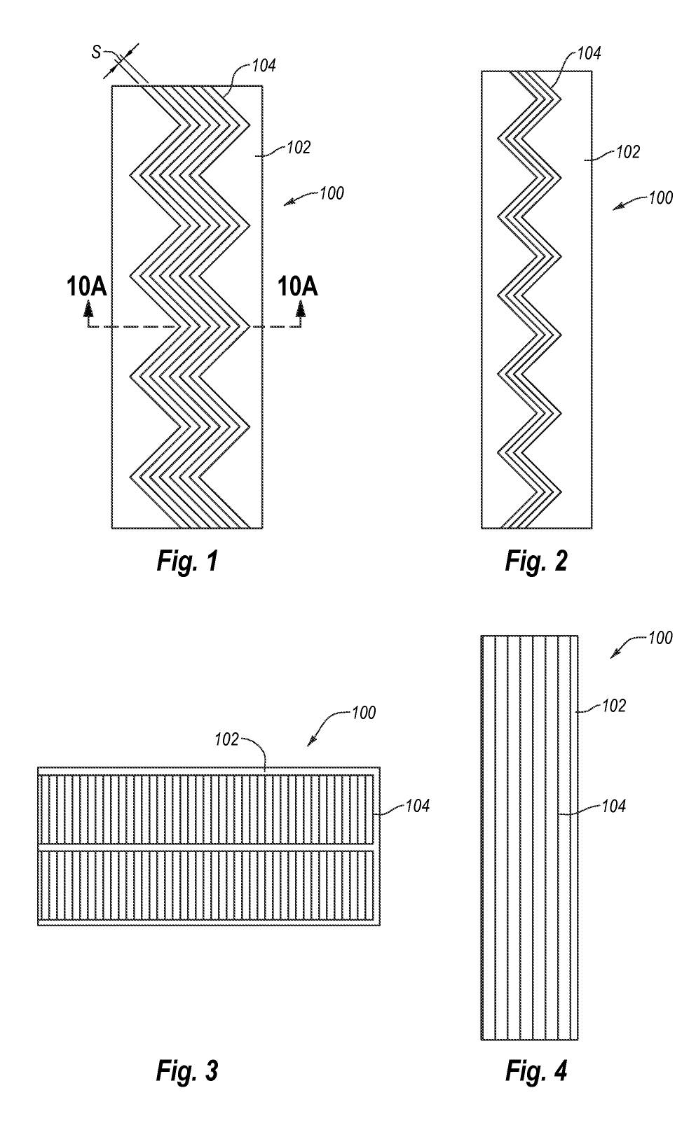

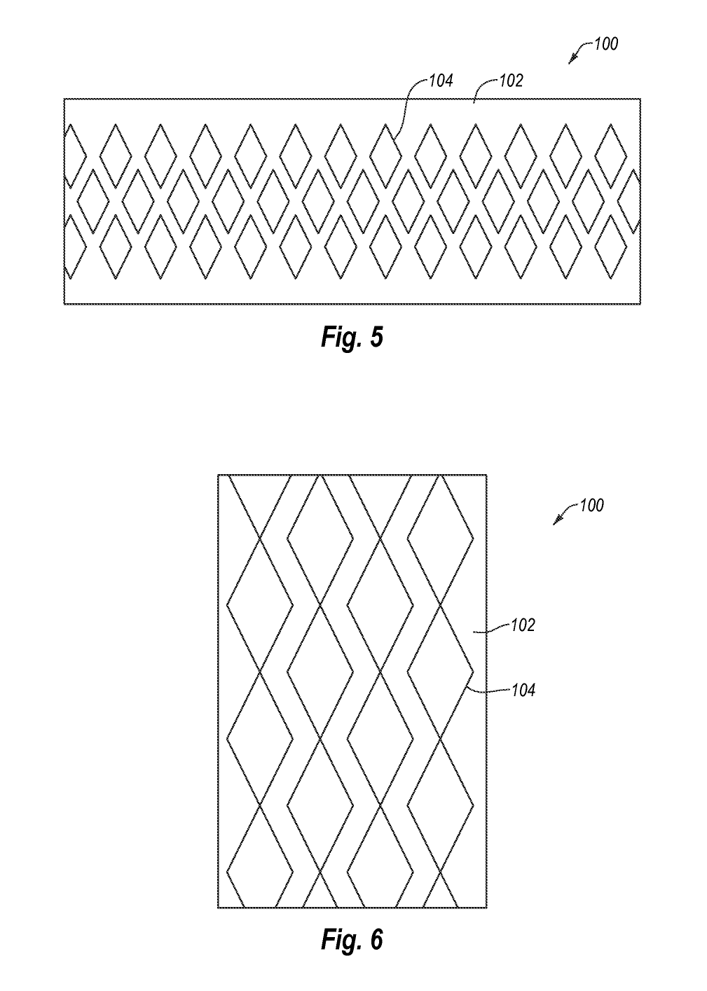

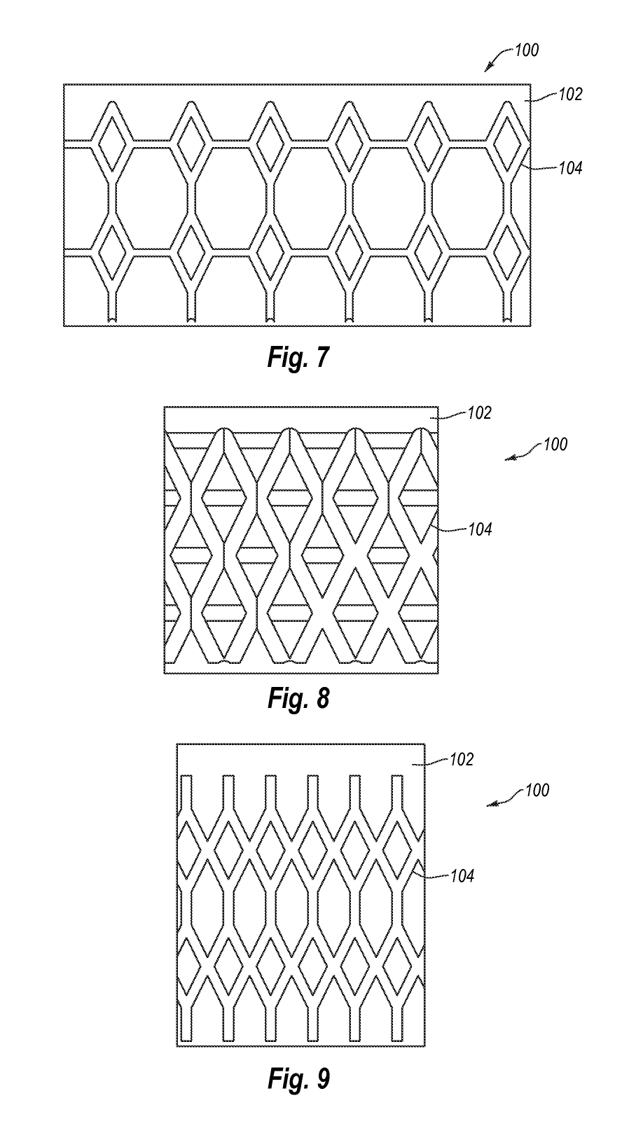

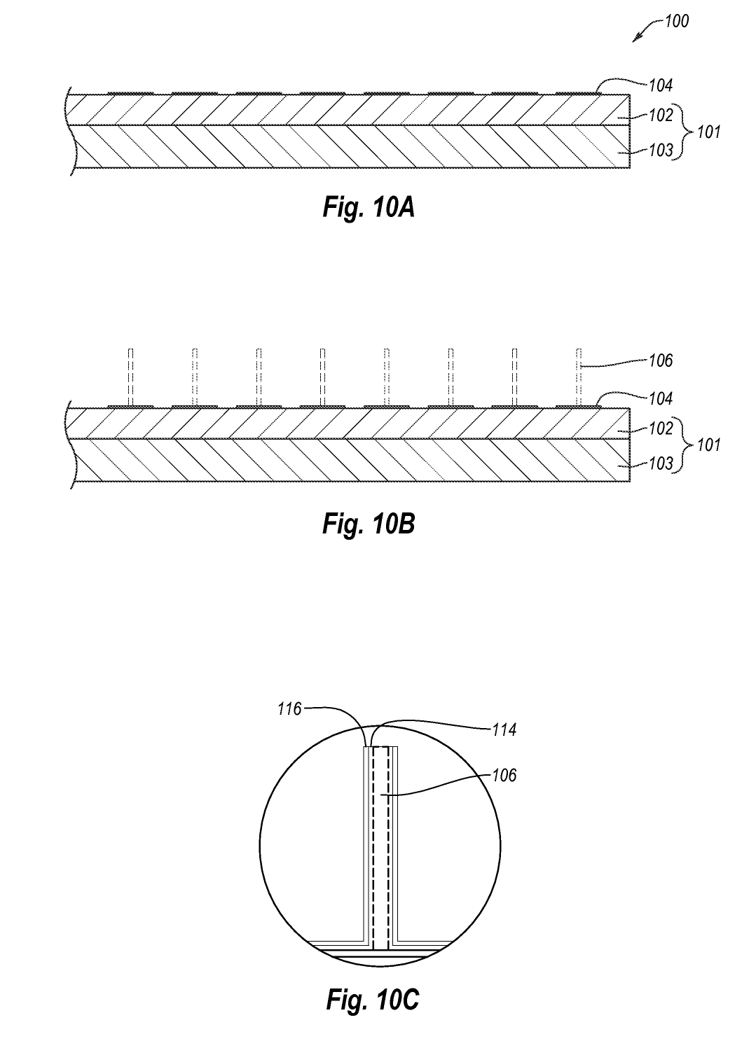

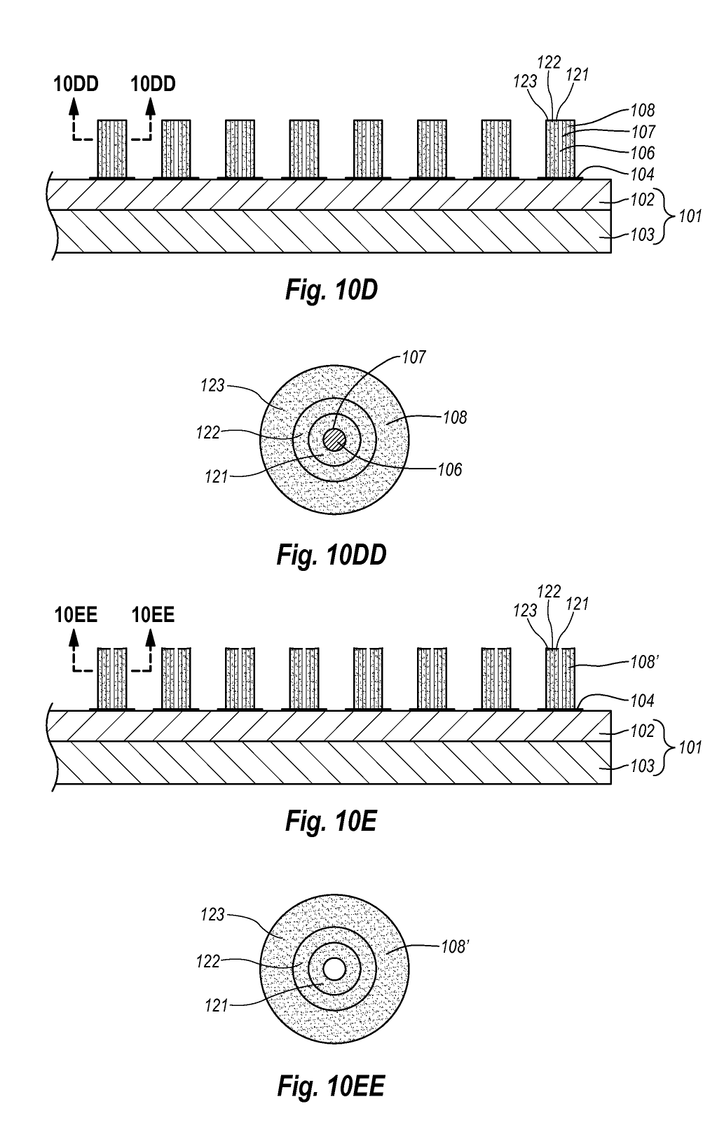

The catalyst layer may be applied in a selected linear pattern, a selected non-linear pattern, or other selected pattern, or may be applied over substantially an entire surface of the backing layer. Various embodiments of patterns for the catalyst layer are shown in FIGS. 1-9. For example, FIGS. 1 and 10A show a TLC plate intermediate structure 100 including a substrate 101 including a backing layer 102 disposed on a base 103 and a catalyst layer 104 formed on backing layer 102 in a non-linear zigzag pattern, with the patterned catalyst represented by the dark lines. In some embodiments, periodic breaks may be formed in some or all of the zigzag portions of catalyst layer 104 to provide a more uniform average mobile phase velocity to the TLC plate to be ultimately formed. FIG. 2 illustrates another embodiment of a zigzag pattern for catalyst layer 104, with the patterned catalyst represented by the dark lines (e.g., a series of “hedges” separated from one another by adjacent flow channels). FIGS. 3 and 4 each show a TLC plate intermediate structure 100 including substrate 101 having backing layer 102 disposed on a base and a catalyst layer 104 formed on backing layer 102 in substantially parallel patterns according to another embodiment, with the patterned catalyst represented by the dark lines. FIGS. 5 and 6 each shows a TLC plate intermediate structure 100 including substrate 101 having backing layer 102 disposed on a base and a catalyst layer 104 formed on backing layer 102 in various repeating diamond patterns according to various embodiments, with the diamonds representing the catalyst. FIGS. 7-9 each shows a TLC plate intermediate structure 100 including a substrate 101 having backing layer 102 disposed on a base and a catalyst layer 104 formed on backing layer 102 in different honeycomb-like patterns according to various embodiments. FIGS. 1 and 2 and 5-9 each show a non-linear catalyst pattern, while the patterns of FIGS. 3 and 4 show generally linear catalyst patterns.

The catalyst layer 104 may be patterned to exhibit any desired spacing between adjacent portions of the patterned catalyst layer 104. For example, an average bed spacing “S” is shown in FIG. 1. In an embodiment, an average bed spacing between adjacent portions of patterned catalyst layer 104 is between about 0.2 μm and about 50 μm, more particularly between about 0.5 μm and about 20 μm, and most particularly between about 1 μm and about 10 μm (e.g., about 10 μm). One of ordinary skill in the art will appreciate that catalyst layer 104 may be formed so as to have any desired pattern and/or spacing “S.” In another embodiment, the catalyst layer 104 may be formed so as to cover substantially the entire backing layer 102, lacking any particular distinct pattern. In some embodiments, catalyst layer 104 is spaced inwardly from edges of backing layer 102 in order to substantially prevent growth of CNTs on the edges. In some embodiments, the spacing “S” may vary in one or two directions, such as from zigzag portion to zigzag portion.

With catalyst layer 104 formed on backing layer 102, TLC plate intermediate structure 100 may be placed onto a suitable support (e.g., a quartz support) within a furnace and heated to a temperature within a range of about 600° C. to about 900° C., more particularly between about 650° C. to about 850° C., and even more particularly to between about 700° C. to about 800° C. (e.g., about 750° C.). Prior to CNT growth, the catalyst layer 104 may be annealed in an annealing process in which H₂ or another process gas is flowed over the catalyst layer 104 (e.g., within a fused silica tube) while the temperature is increased from ambient temperature to the temperature at which CNT growth will occur. Flow of H₂ may be about 300 cm³/min or any other suitable flow rate.

A process gas (e.g., H₂, ammonia, N₂, or combinations thereof) and a carbon-containing gas (e.g., acetylene, ethylene, ethanol, methane, or combinations thereof) are introduced and flowed over the catalyst layer 104. A noble gas (e.g., argon) may also be included with the carbon-containing gas stream to control the rate of growth of CNTs on and over the catalyst layer 104. Additives, such as water, may be added during the CNT growth process such that the additive and/or reaction products thereof may be present in the growth mixture. Flow of the process gas and carbon-containing gas (e.g., ethylene) may be within a ratio of about 0.5:1 to about 1, more particularly between about 0.55:1 and about 0.85:1, and even more particularly between about 0.6:1 and about 0.8:1.

Once the desired height of CNT growth is achieved, flow of the process gas and carbon-containing gas are turned off, and the furnace chamber may be purged with flow of a noble gas (e.g., argon) as the furnace is partially cooled, for example to a temperature between about 100° C. to about 300° C., more particularly between about 150° C. to about 250° C., and even more particularly to between about 175° C. to about 225° C. (e.g., about 200° C.).

In an embodiment, and in order to achieve a higher aspect ratio of average CNT length to average CNT diameter, a “start/stop” method may be employed. For example, the carbon-containing gas may be turned off during CNT growth, causing the CNTs to grow in a myriad of directions. This type of growth may be desired in some embodiments, as it may lead to more mechanically stable CNTs (e.g., such adjacent CNTs may be more likely to contact and/or at least partially intertwine with one another).

FIG. 10B is a cross-sectional view of an embodiment of a structure similar to that of FIGS. 1 and 10A in which CNTs 106 have been grown on and over catalyst layer 104 disposed on a backing layer which is further disposed on a base 103. CNTs 106 may be grown to extend longitudinally away from the substrate 101. For example, the CNTs may extend substantially perpendicular (i.e., vertical) to respective surfaces of catalyst layer 104 and substrate 101. Grown CNTs 106 may be single walled or multi-walled, as desired. Grown CNTs 106 may have an average diameter between about 3 nm and about 20 nm, more particularly between about 5 nm and about 10 nm (e.g., about 8.5 nm) and an average length of about 1 μm to about 2000 μm, about 5 μm to about 1000 μm, about 10 μm to about 500 μm, about 20 μm to about 400 μm, about 20 μm to about 200 μm, about 100 μm to about 300 μm, about 10 μm to about 100 μm, or about 20 μm to about 200 μm. The grown CNTs 106 may exhibit an average aspect ratio (i.e., ratio of average length to average diameter) of about 10,000 to about 2,000,000, such about 10,000 to about 1,000,000, or about 100,000 to about 750,000.

The average length to which CNTs 106 are grown may be chosen based on the particular chromatography application for which the resulting TLC apparatus will be used. For example, the average length of the CNTs 106 may be about 2 μm to about 100 μm for ultra-thin layer chromatography (“UTLC”), the average length of the CNTs 106 may be about 100 μm to about 300 μm for high-performance thin layer chromatography (“HPTLC”), and the average length of the CNTs 106 may be about 500 μm to about 2000 μm for preparative liquid chromatography (“PLC”).

Additional details regarding growth of CNTs 106 may be found in U.S. patent application Ser. No. 12/239,281 U.S. Pat. No. 7,756,251, and U.S. Provisional Patent Application No. 60/995,881, each of which incorporated herein, in its entirety, by this reference. Further details may be found in U.S. patent application Ser. No. 13/035,645, which is also incorporated herein by reference in its entirety.

Although CNTs 106 are illustrated as being uniformly spaced, CNTs 106 may be at least partially intertwined with each other to form a vertical wall of CNTs 106. Furthermore, adjacent “hedges” of CNTs 106 may comprise a plurality of grouped CNTs, which may be at least partially intertwined with each other (e.g., more than one CNT may be grown side by side with the illustrated CNT on the shown catalyst layer 104). Only one CNT is shown on each catalyst layer 104 for simplicity. Such hedges of CNTs may be separated by a flow channel between another adjacent hedge. As previously discussed, the at least partial intertwining and/or contact of CNTs 106 with each other helps reduce, limit, or prevent the vertical wall of CNTs 106 from bending out of plane. Furthermore, the rigidity of the wall of CNTs 106 may be further enhanced to reduce, limit, or prevent out of plane bending thereof by patterning catalyst layer 104 in a selected non-linear pattern (e.g., the pattern shown in FIG. 1) and growing respective portions of CNTs 106 on the individual non-linear portions of catalyst layer 104 to form respective walls of CNTs 106.

The CNTs are used as a framework to be infiltrated or coated with a material that may increase the mechanical stability of the overall structure and provide a stationary phase for use in chromatography applications. Optionally, one or more priming layers may be applied to the CNTs in preparation for infiltration, which priming may further increase the mechanical stability of the overall structure, and/or act as adhesion promotion layers for subsequent layers. For example, application of the priming layer(s) may contribute to prevention or minimization any tendency of the resulting stationary phase to delaminate, buckle, or otherwise separate from the substrate 101.

Application of any priming layer(s) is optional, as it has been found that results exhibiting good mechanical stability and good stationary phase adhesion can be obtained with less complexity by ozone treating the formed CNTs. Where a priming layer is present, the priming layer(s) may themselves be oxidized. The oxidation (e.g., ozone treatment) process results in formation of surfaces that are enriched in oxygen moieties, which are helpful in promoting subsequent deposition of the stationary phase coating or precursor thereof. In the case of direct depositing of silicon nitride onto the CNTs (such as by LPCVD), no priming layer or oxidation on the CNTs is required.

FIG. 10C shows optional priming layers 114, 116 applied to CNTs 106. Each priming layer 114, 116 may be relatively thin. For example, the thickness of any given priming layer may be from about 1 nm to about 20 nm, from about 2 nm to about 15 nm, or from about 2 nm to about 12 nm. The priming layer may thus be significantly thinner than a subsequently applied stationary phase or precursor thereof (which may typically be about 100 nm in thickness).

Materials used for priming may be the same or similar materials as those used for infiltration with the stationary phase or its precursor. Examples of such priming materials include, but are not limited to, elemental silicon, silicon dioxide, silicon nitride, elemental aluminum, aluminum oxide, elemental zirconium, zirconium oxide (e.g., zirconium dioxide), elemental titanium, titanium oxide, amorphous carbon, graphitic carbon, ozone and combinations of the foregoing. In an embodiment, the priming layers are selected from amorphous carbon, silicon dioxide, and combinations thereof. For example, in an embodiment, priming layer 114 adjacent to CNTs 106 may include silicon dioxide, while priming layer 116 adjacent to priming layer 114 may comprise amorphous carbon.

Application of the one or more priming layers may be achieved at appropriate temperatures. For example, deposition of amorphous carbon can be carried out at a temperature at a somewhat higher range than that described above relative to CNT growth. For example, deposition of amorphous carbon can be carried out from about 800° C. to about 1000° C., from about 850° C. to about 950° C., or about 900° C. while flowing ethylene and argon over the CNTs. In an embodiment, the amorphous carbon priming layer is formed to be not more than about 10 nm thick, such as from about 2 nm to about 8 nm thick, or from about 3 nm to about 5 nm thick.

Deposition of alumina as a priming layer by atomic layer deposition (“ALD”) may be carried out at significantly lower temperatures, e.g., from about 150° C. to about 350° C., from about 200° C. to about 300° C., or about 250° C. while cycling trimethylaluminum and water in a serial, repeating process (e.g., in an A-B-A-B fashion) for a desired number of cycles. Deposition of about 0.1 nm per cycle is typical. In an embodiment, the alumina layer is formed to be from about 5 nm to about 15 nm thick, or from about 6 nm to about 12 nm thick. Additional details of priming layer(s) and their deposition may be found in U.S. Pat. No. 8,702,984, which is incorporated herein, in its entirety, by this reference.

CNTs 106 may be subjected to an oxidation priming process to form a surface enriched in oxygen moieties. For example, priming using oxidation by ozone treatment may be used as an alternative to using priming layers. Ozonation appears to increase the number of nucleation sites on the CNTs by at least partially oxidizing them (but not burning them away), thereby facilitating conformal growth of silica or another stationary phase or precursor thereof. Ozone treatment, for priming or otherwise may be straightforward, involving passing gaseous ozone over the patterned CNT forest, substantially as disclosed in U.S. patent application Ser. No. 13/773,969 which is incorporated herein in its entirety by this reference.

CNTs 106 may be infiltrated and/or coated with a stationary phase or stationary phase precursor, which may occur after an optional oxidation priming process. Referring to FIG. 10D, after growth, CNTs 106 may be infiltrated with one or more infiltrants (e.g. a precursor gas) so that a coating 108 deposits on the CNTs 106 or on a surface adjacent to (in cases of primed surfaces) the CNTs 106. FIG. 10DD shows a close up transverse cross-sectional view through a single CNT 106, showing formation of stationary phase 108 (or precursor thereof) over oxygen enriched surface 107. The coating 108, as depicted in FIGS. 10D and 10DD, may have a layered conformation including a number of layers 121, 122, 123, and optionally more layers. In embodiments, the coating may comprise more or less than three layers, such as 1 layer or more, 2 layers, 4 layers, or 5 layers. In embodiments, the coating may not have a strictly layered conformation, instead having portions of layers infiltrated into portions of adjacent layers. The layers 121, 122, and 123 may include any material described herein suitable to form a stationary phase or stationary phase component. In an embodiment, an inner layer 121 may comprise silicon nitride, a middle layer 122 may comprise a fluorescent material (e.g., zinc oxide) or other photoluminescent material, and an outer layer 123 may comprise silicon nitride. In an embodiment, an inner layer 121 may comprise silicon nitride, a middle layer 122 may comprise zinc oxide, and a layer 123 may comprise silicon dioxide, and a further outer layer may comprise silicon nitride.

Generally, embodiments of the invention contemplate incorporating a fluorescent material or other type of photoluminescent material onto, into, or as a portion of a plurality of elongated structures for use in a TLC plate. The fluorescent material or other type of photoluminescent material may be coated, bonded, formed, infiltrated or otherwise incorporated into the TLC plate. For example, zinc oxide particulates may be adhered to or distributed upon the CNTs (e.g., before or after coating with silicon, before or after coating with silicon nitride or silicon dioxide, or at any point in the formation of the TLC plate).

Coating 108 comprises a stationary phase and/or a precursor to the stationary phase comprising a material, a mixture of materials, layers of materials 121, 122, and 123, or combinations of the foregoing. Examples of materials for coating 108 include, but are not limited to, elemental silicon (e.g., deposited from a precursor SiH₄ gas), silicon dioxide, silicon nitride (e.g., deposited via low pressure chemical vapor deposition (“LPCVD”) using dichlorosilane (“DCS”) and ammonia as precursors), elemental aluminum, aluminum oxide, elemental zirconium, zirconium oxide (e.g., zirconium dioxide), elemental titanium, titanium oxide, amorphous carbon, graphitic carbon, zinc oxide (e.g., deposited via LPCVD or ALD using dimethyl zinc (“DMZ”) or diethyl zinc (“DEZ”) and water and/or oxygen or an oxygen plasma), and combinations of the foregoing. Because the choice of coating 108 may change the selectivity of the resulting TLC plate, coating 108 used for manufacture of any given TLC plate may be selected depending on the intended use of the TLC plate. Because the choice of coating 108 may change the fluorescence of the resulting TLC plate, materials and/or layers of the coating 108 may be selected based upon the resulting fluorescence or effect on fluorescence of a material therein. For example, zinc oxide in the coating 108 may allow the resulting TLC plate to fluoresce under short wavelength UV light (e.g., 254 nm).

In an embodiment, infiltration of CNTs 106 may be accomplished using chemical vapor deposition (e.g., LPCVD) or another suitable deposition process (e.g., ALD or pseudo-ALD). Silicon nitride may be directly deposited by cycling dichlorosilane (“DCS”) and ammonia in any fashion including but not limited to serial, repeating (e.g., in an ABAB fashion) fashion. For example, where depositing silicon nitride, the TLC plate intermediate structure shown in FIG. 10B may be placed into an LPCVD furnace and at about 780° C. Under such conditions, the DCS and ammonia reactants flow over CNTs 106 to cause a layer of (see FIG. 10D) of silicon nitride to form on CNTs 106. In embodiments, a thickness per cycle can be achieved, for a final silicon nitride thickness after a desired number of cycles (e.g., 1-10 cycles), or after a certain amount of time in the LPCVD reactor.

In embodiments, a stationary phase may be directly deposited onto CNTs 106, including primed CNTs. For example, deposition processes for SiO₂ include direct SiO₂ deposition by LPCVD, ALD, or by other CVD processes with SiH₄ and O₂, 3DMAS and O₂ plasma, or SiH₂Cl₂ with N₂O, or by other methods for CNT infiltration that will be apparent to one of skill in the art in light of the present disclosure. As another example, silicon nitride may be deposited directly or indirectly deposited onto the CNT's via low pressure LPCVD using DCS and ammonia (NH₃) as precursors. In a further example, zinc oxide may be directly or indirectly deposited onto a CNT via LPCVD or ALD using DMZ or DEZ and water and/or oxygen or an oxygen plasma. Zinc oxide in the coating or otherwise incorporated into the TLC plate may allow the resulting TLC plate to fluoresce under UV light (e.g., 254 nm wavelength). The inventors have successfully performed deposition of silica using pseudo-ALD, LPCVD of silicon nitride, and zinc oxide directly onto CNTs. Further materials may be coated onto CNTs using LPCVD.

ALD processes may be used to infiltrate CNTs 106 with a coating (e.g., a conformal coating) of a selected material having chromatographic abilities, fluorescent abilities, or which may be subsequently processed to result in such abilities. The above-described pseudo-ALD process enables deposition of a relatively very thick layer of silica in a single cycle (e.g., about 5 nm to about 15 nm per cycle). Other similar processes may alternatively be used. For example, ALD may be used to infiltrate CNTs with SiO₂. One such process may use SiCl₄ and water at a selected temperature. SiCl₄ is introduced into the chamber containing CNTs 106 and is allowed to react therewith for a predetermined time. After finishing the self-limiting chemisorptions/physisorption process, which may include removing most of the unbound silicon precursor (SiCl₄), water is introduced into the chamber which reacts with the bound SiCl₄ to produce a conforming layer of SiO₂ on CNTs 106. Most, or all, of the water in the chamber may then be removed. This process is repeated until a predetermined film thickness of SiO₂ is achieved. Such an ALD process may be significantly slower, providing only a ca. 0.1 nm thickness of silica deposition per cycle. Thus, the pseudo-ALD process may be faster, as it provides 50 to 150 times greater deposition per cycle.

Other ALD-like processes may also be used. Another ALD-like process may include introduction of SiCl₄, but excess SiCl₄ may or may not be entirely removed by pumping before water is introduced. In turn, excess water may or may not be entirely removed before SiCl₄ is introduced. By not entirely removing excess reagent, as would be appropriate for a true ALD process, faster deposition of SiO₂ may be possible. This same strategy of incomplete removal of material could be contemplated for other ALD chemistries that could be used to infiltrate CNTs 106. It is also noted that perfect conformal coating of uniform thickness, or layers of uniform thickness on CNTs 106 may not always be desirable. An infiltration process may be designed to produce a rough non-uniform thickness of a layer or coating so as to increase the surface area of the support.

In embodiments, CNTs 106 may be infiltrated or coated and then oxidized, if needed or desired. After deposition of at least a partial coating (e.g., a layered or particulate coating), the material may be placed into a furnace in ambient air (e.g., an oxidizing environment) and heated to between about 500° C. and about 1100° C. (e.g., about 850° or 900° C.) for between about 1 and about 10 hours, such as about 2 to about 8 hours, about 3 to about 6 hours, about 4 hours, or about 5 hours. This process converts elemental silicon to silicon dioxide, and silicon nitride to silicon dioxide while also removing CNTs 106 by oxidizing them into CO and/or CO₂ thereby leaving elongated stationary phase structures made from silicon dioxide, silicon nitride, and/or any other suitable layer or coating materials without any significant amount of CNTs 106 filling. In additional embodiments, the CNTs 106 may not be removed or they may only be partially removed. In some embodiments, oxidative heating durations, as noted above, may be selected based on the thickness of one or more of the layers or CNT and the desired depth or amount of oxidation therein.

In some embodiments, silicon may be infiltrated directly into or onto the plurality of CNTs. For example, silicon infiltration may be achieved by flowing SiH₄ at a rate of about 20 cm³/min at a temperature of about 530° C. with a pressure of about 160 mTorr for about 1-3 hours, depending on film thickness (degree of infiltration) desired. In the case in which the infiltrant is a silicon precursor gas such as silane, coating 108 may comprise silicon. However, as discussed above, other precursor gases may be used so that coating 108 may be formed from aluminum or zirconium, or oxides thereof (e.g., use of TMA/TTBS results in a coating of silicon dioxide). Depending on the infiltrant or layer material selected, coating 108 may at least partially or substantially coat the entire array or plurality of CNTs 106 only, or it may also coat the intervening portions of backing layer 102 and catalyst layer 104 between the CNTs 106, resulting in a TLC plate that is one coherent mass. Such a coating may be oxidized as described above.

Coating 108, optionally comprising layers 121, 122, and 123, on respective primed CNTs 106 shown in FIG. 10D forms respective high aspect ratio structures exhibiting an elongated annular geometry (e.g., a substantially hollow cylinder). CNTs 106 act as templates around which the coating material deposits. In some embodiments, the coating or layers of the coating 108 may be porous or non-porous. The particular aspect ratio of the elongated structures made from coating 108 depends on the height of the template CNTs 106, the deposition time, the process temperature (e.g., temperature of infiltrant and of CNTs 106), or combinations of the foregoing process parameters.

An average aspect ratio (i.e., ratio of average length to average diameter) of the plurality of elongated structures defined by coating 108 coating respective CNTs 106 may be about 100 to about 2,000,000, such about 10,000 to about 1,000,000, about 200 to about 10,000, about 10,000 to about 100,000, or about 100,000 to about 750,000. The average radial thickness of coating 108 coating the CNTs 106 may be about 10 nm to about 250 nm, more particularly about 20 nm to about 150 nm, and even more particularly about 50 nm to about 125 nm (e.g., about 50 to 100 nm). The average length of the elongated structures defined by coating 108 may be substantially the same or similar as the template CNTs 106.

In some cases, random growth of CNTs 106 followed by infiltration and optionally oxidation of coating 108 can pose a potential problem. During the oxidation process of converting silicon to silicon dioxide, the material undergoes a volume expansion due to the addition of the oxygen. The volume expansion may cause the material to delaminate from the backing, particularly during longer, more complete oxidation times and at relatively higher oxidation temperatures. Even if delamination does not appear to have occurred initially, the material may easily buckle and flake away as a result of a slight bump or touch because of the expansion. One way to reduce, minimize, or eliminate such delamination, flaking, or buckling of the material from the backing is by patterning (e.g., zigzag or other non-linear) the CNT growth catalyst, which places voids into the overall structure allowing for volume expansion during the oxidation step. In addition, patterning of the stationary phase medium on the micron-scale may improve separation efficiency. Another way to reduce minimize or substantially eliminate such undesirable characteristics is by directly depositing a stationary phase material (e.g., silicon dioxide) rather than depositing a stationary phase precursor that is later oxidized.

In addition, ozone treatment of the CNTs prior to infiltration may further aid in reducing, minimizing, or eliminating such distortion. Furthermore, ozone treatment allows direct deposition of the stationary phase (e.g., silicon dioxide), without the need for any priming layer(s), and rather than requiring deposition of a precursor (e.g. silicon) that is later oxidized. Thus, in at least some embodiments, oxidation to remove the CNTs may not be required to oxidize silicon to silicon dioxide, and can be achieved at a lower temperature than where the oxidation step also oxidizes the silicon to silicon dioxide. TLC plates fabricated without the use of priming layers, where the priming layer steps are replaced with an oxidation process, exhibit a similar appearance (i.e., good mechanical stability and the absence of distortion of the zigzag pattern). Replacement of the act of priming with an oxidation process may result in a significantly simplified manufacture process, with comparable, if not superior, results.

The selected zigzag pattern may include any of various angles greater than 0° and less than 180° between the particular portions of the zigzag. For example, the zigzag patterns shown in FIGS. 1, 2, 11A, and 11B may exhibit an angle of about 70° to about 90° between adjacent portions of the zig and zag of the pattern therein.

As described above, an average bed spacing between adjacent portions of patterned catalyst layer 104 may be from about 0.25 μm to about 50 μm, more particularly from about 0.5 μm to about 20 μm, about 10 μm to about 30 μm, and most particularly from about 1 μm to about 15 μm, about 3 μm, or about 10 μm. This spacing could be described as distance center to center from one “hedge” to another. The “hedge” width may be from about 0.25 μm to about 15 μm, from about 0.5 μm to about 10 μm, from about 1 μm to about 5 μm, from about 3 μm to about 8 μm, or from about 3 μm to about 4 μm. The growth of CNTs 106 followed by infiltration with infiltrant and/or growth of coating 108 around CNTs 106 results in less spacing between adjacent elongated structures defined by coating 108 as they grow laterally outward and towards one another.

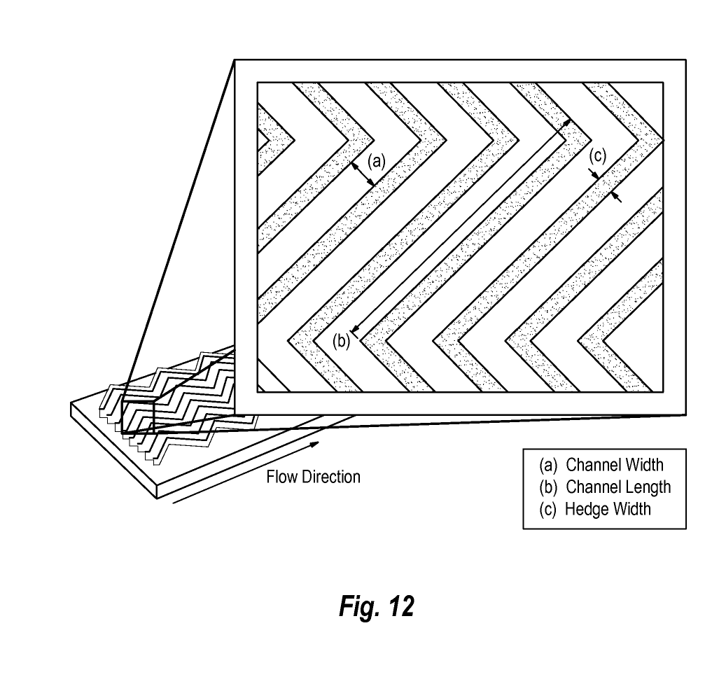

For example, an average spacing between adjacent elongated structures (i.e., “flow channel” width) defined by coating 108 may be between about 0.1 μm and about 30 μm, more particularly between about 0.5 μm and about 10 μm, and most particularly between about 1.5 μm and about 8 μm (e.g., about 3 μm to about 6 μm). Such spacing results in a bulk structure having very high bulk porosity i.e., the spacing between adjacent structures act as pores through which the mobile phase and sample carried therewith advance as a result of capillary action through the flow channels. In one embodiment, the flow channel width may be greater than the hedge width (e.g., about 5 μm versus about 4 μm, about 4 μm versus about 3 μm, about 2 μm versus about 1 μm, about 5 μm versus about 3 μm, about 6 μm versus about 3 μm, or about 5 μm versus about 4 μm, respectively). Flow channel length may be from about 0.5 μm to about 500 μm, about 10 μm to about 100 μm, about 0.5 μm to about 25 μm, about 1 μm to about 15 μm, about 1.5 μm to about 8 μm, or about 25 μm to about 75 μm. When present, porosity of any individual coating 108 (i.e., as opposed to bulk porosity resulting from spacing between adjacent structures) may also contribute to the overall porosity of the TLC plate. Flow channel width “a”, channel length “b”, and hedge width “c” for an exemplary zig-zag pattern are clearly shown in FIG. 12.

In an embodiment, CNTs 106 may be partially or substantially completely removed once the coating 108 has been deposited onto CNTs 106. For example, the TLC plate intermediate structure shown in FIG. 10D may be placed into a furnace and heated in the presence of an oxidizing atmosphere (e.g., an oxygen atmosphere or air) so as to remove (e.g., burn off) substantially all of CNTs 106, leaving only coating 108 disposed on the backing layer 102 and catalyst layer 104 of TLC plate substrate 101. In some embodiments, the stationary phase coating 108, or at least one layer therein, does not require further oxidation prior to use (e.g., it is deposited as silica rather than silicon).

In other embodiments, such an oxidation step may also serve to convert coating 108 or a layer thereof into the stationary phase material by oxidizing the as-deposited coating 108 or one or more layers thereof if it is not already a chromatography capable stationary phase material. For example, if coating 108 or a layer 121, 122, or 123 therein is silicon, silicon nitride, aluminum, or zirconium, it may be oxidized to silicon oxide, silicon dioxide, aluminum oxide, or zirconium oxide, respectively. An embodiment of a method for removal of the CNTs 106 may include oxidizing coating 108 using an oxygen plasma. Other methods for at least partially removing CNTs 106 may include dissolution of CNTs 106, or removal by any method.

Where the oxidation step also oxidizes the as deposited coating 108 into an oxide stationary phase, the temperature may need to be higher than where the oxidation step is not required to oxidize the deposited coating. For example, where the coating is oxidized during the oxidation step, the temperature may be from about 800° C. to about 1000° C. (e.g., about 850° C. to 900° C.). Where the oxidation step is not required to oxidize the coating 108 (e.g., because coating 108 was already deposited as a desired oxide such as silicon dioxide), the temperature may be lower (e.g., not more than about 750° C., not more than about 700° C., not more than about 650°, not more than about 600° C., or from about 500° C. to about 650° C., or about 600° C.). Methods that deposit coating 108 as an oxide rather than a precursor to an oxide stationary phase may be beneficial, as the lower processing temperature may further increase the mechanical stability of the resulting stationary phase of a TLC plate. In other words, because of the lower temperature and the fact that no oxidizing of the coating 108 occurs during the oxidation step, less distortion of the zig-zag or other pattern may occur, providing increased mechanical stability and durability.

FIG. 10E is a cross-sectional view of the structure shown in FIG. 10D in which the CNTs 106 have been removed. FIG. 10EE is a close up cross-sectional view of stationary phase structures 108′ (i.e., coating having no CNT therein), including optional layers 121, 122, and 123, once CNTs 106 have been burned off. FIG. 10E clearly shows the overall high aspect ratio configuration of the stationary phase structures 108′, optionally comprising the layers 121, 122, and 123. The dimensions of the plurality of elongated stationary phase structures 108′ may be substantially the same or similar dimensions as the plurality of elongated structures defined by coating 108 prior to oxidation of CNTs 106. The oxidation process may occur for at least about 1 hour, more particularly at least about 10 hours, and most particularly for at least about 15 hours. Somewhat reduced processing times may be provided where oxidation of the coating 108 is not required (e.g., about 15 to about 24 hours is typically sufficient). Notwithstanding the illustration of the elongated structures having a hole therethrough, during oxidation (e.g., heating process), the material surrounding the CNTs 106 may flow or rearrange or expand in such a way such that the hole in the elongated structure formerly occupied by the now oxidized CNT is at least partially filled with other materials or at least partially oxidized materials, such as those from the layers 121, 122, and 123.

As shown in FIGS. 10E and 10EE, in embodiments in which the coating 108 or layers 121, 122, 123 of the coating are deposited by ALD or an ALD-like process (e.g., ALD deposition of silicon oxide), the resultant elongated stationary phase structures may be hollow elongated cylinders, optionally including a plurality of layers therein, with the hollow being where a CNT 106 was located. Where the oxidation step may also at least partially oxidize coating 108 or one or more of layers 121, 122, 123 therein. Depending on the extent of the oxidation process, the elongated stationary phase structures 108′ may be substantially solid nanowires in which the space previously occupied by the CNTs 106 is consumed or filled by the oxide. In an embodiment, the inner layer 121 may comprise silicon nitride, the middle layer 122 may comprise zinc oxide and/or other fluorescent material, and the outer layer 123 may comprise silicon nitride, at least one of which may be at least partially oxidized. In an embodiment, the inner layer 121 may comprise silicon nitride, the middle layer 122 may comprise a fluorescent material (e.g., zinc oxide), the layer 123 may comprise silicon dioxide, and an optional further outer layer may comprise silicon nitride, at least one of which may be at least partially oxidized. For example, the innermost layer and the outermost layer may be at least partially oxidized during removal of the CNT 106 by oxidation, wherein one or more inner layers remain substantially unoxidized. In embodiments, at least a portion of each of the layers may be at least partially oxidized. Zinc in such layers may diffuse into another layer or material during heating. In some embodiments, zinc may comprise or may be deposited or adhered to at least a portion of the hollow elongated structures (or precursors thereof) and may be oxidized to form zinc oxide.

Removal of CNTs 106 before use of the TLC plate may prevent CNTs 106 from interfering (e.g., through a secondary interaction, such as those due to differing materials in the stationary phase structures) with separation of an analyte mixture during use of the TLC plate. In addition, removal of the CNT's 106 (e.g., oxidation) results in a white and/or transparent or semi-transparent stationary phase; thereby making evaluation of the chromatography results easier than if the stationary phase is black or brown. In embodiments in which the coating 108 comprises amorphous carbon, the CNTs 106 may not be removed, as both the coating 108 and CNTs 106 comprise carbon, thereby substantially eliminating the possibility of a secondary interaction as a result of the CNTs 106 being present in the stationary phase formed during infiltration.

In a similar manner, it may be desirable, in some embodiments, that the coating 108 substantially fully coats and covers any priming layer(s). Any amorphous carbon priming layer may simply be burned away with the CNTs. In embodiments without any alumina priming layer, the absence of the alumina priming layer can be advantageous because exteriorly exposed alumina may interfere with the separation results achieved by the TLC plate.

In some embodiments, the stationary phase structures 108′ comprise a material that is white, off white, transparent, or generally light in color so that the compounds of the mobile phase separated during use of the TLC plate are visible on the surface of the TLC plate after being developed. Silicon, silicon nitride, and/or silicon dioxide are examples of materials that provide such a color contrast.

In embodiments, a fluorescent material (e.g., ZnS, zinc silicate, or ZnO) or other photoluminescent material may be incorporated in the TLC plate to produce a photoluminescently active TLC plate. This may be accomplished by depositing a thin film within the chromatographic support. This may also be accomplished by depositing a thin film or one or more layers of a photoluminescent material on the CNT, on the coating, or as a layer in the coating. This may be done either in the liquid or gas phase. ALD, along with other CVD or liquid phase processes, may be used to place inorganic species into or onto the chromatographic support. For example, the photoluminescent material may at least partially coat and/or may be incorporated in the coating 108 and stationary phase structures 108′, may at least partially coat intervening portions of backing layer 102 between the stationary phase structures 108′, or both. In an embodiment, the photoluminescent material may be provided by depositing nanoparticles of a fluorescent inorganic material from a solution or slurry onto at least a portion of the CNTs, the stationary phase structures, the backing support, or combinations thereof. Such deposition of nanoparticles may be done at any step in the manufacturing process, without limitation.

The following embodiments include portions of materials iteratively deposited onto CNTs, the deposited materials may exhibit a substantially layered conformation, such as that depicted in FIGS. 10D-10EE, to form a coating 108 or 108′, and/or portions of the materials of the layers may be substantially intermixed via infiltration of one material into the structure of the CNTs and/or other materials, such that there is no discernable boundary between materials.

In an embodiment, a fluorescent material (e.g., ZnO) or other photoluminescent material may be deposited or infiltrated on a CNT as a portion (e.g., component material or layer material) of a coating 108 or 108′. For example, in an embodiment, a CNT or plurality of CNTs attached to a backing, according to substantially any embodiment described herein, may be infiltrated or coated with silicon nitride via LPCVD using dichlorosilane and ammonia as precursors. Subsequently, zinc oxide may be formed or deposited (e.g., coated, reacted, or infiltrated) onto the silicon nitride via ALD using DMZ or DEZ and water and/or oxygen or an oxygen (O₂) plasma. The zinc oxide material deposited on the silicon nitride material may be covered with a protective layer of silicon dioxide via ALD, which may be further coated or infiltrated with a second portion of silicon nitride using similar LPCVD parameters. The CNT may be removed from the chemical separation structure by heating the coated TLC plate in air at about 1000° C., which also at least partially converts the silicon nitride to silicone dioxide. Each of the foregoing materials may be deposited as a layer on top of a subsequent material, may be substantially infiltrated into one or more of the other materials, or combinations of the foregoing.

The dichlorosilane and ammonia in the LPCVD process described above may be supplied at about 20 sccm and about 80 sccm respectively at about 780° C. In embodiments, the supply of dichlorosilane may be slower or faster than described above, for example, the flow of dichlorosilane used in and LPCVD process to coat a CNT may be more than about 5 sccm, such as about 5 sccm to about 100 sccm, about 10 sccm to about 60 sccm, about 15 sccm to about 50 sccm, about 5 sccm to about 40 sccm, about 10 sccm to about 30 sccm, about 15 sccm, about 20 sccm, about 25 sccm, or about 30 sccm. In embodiments, the supply of ammonia may be slower or faster than described above, for example, the flow of dichlorosilane used in and LPCVD process to coat a CNT may be more than about 20 sccm, such as about 20 sccm to about 200 sccm, about 50 sccm to about 150 sccm, about 60 sccm to about 100 sccm, about 70 sccm to about 90 sccm, about 75 sccm, about 80 sccm, about 85 sccm, or about 90 sccm. In embodiments, the temperature at which the LPCVD occurs may be more than about 650° C., such as about 650° C. to about 900° C., about 700° C. to about 850° C., about 750° C. to about 800° C., or about 760° C. to about 800° C., or about 780° C.

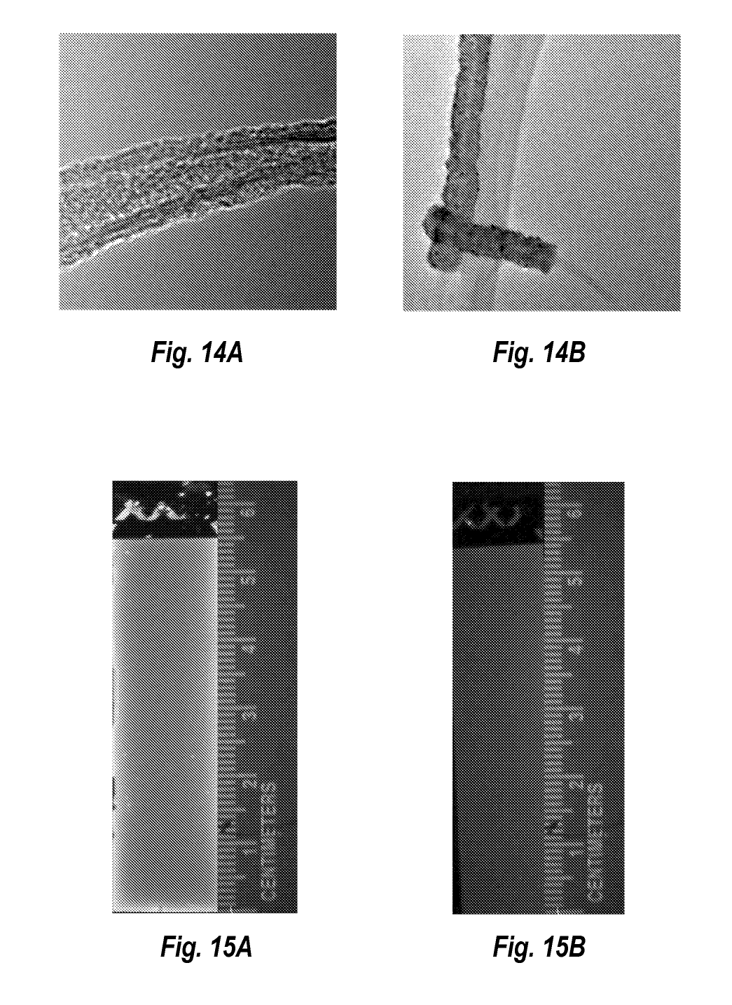

In an embodiment, the zinc oxide may be deposited onto the silicon nitride via ALD using alternating pulses of DMZ and water as precursors with a purge for a duration therebetween utilizing a Fiji F200 ALD system (available from Cambridge NanoTech, Inc.). During the ALD process, zinc from the DMZ reacts with oxygen from the water in a double exchange reaction, thereby forming ZnO. Due to the high surface area of the CNT structures, a high dose of the precursors may be employed. In embodiments, the dosages and pulse times for the ALD process may include a DMZ and water pulse time of 0.06 seconds, four times, with a purge time of 15 seconds. In embodiments, the dosages and pulse times for the ALD process may include DMZ and water pulse time of 0.1 with a purge time of 20 seconds. As depicted in FIGS. 14A and 14B, zinc containing nanoparticles (e.g., ZnO) are deposited on the CNT during the ALD process described above. FIGS. 14A and 14B depict a CNT coated in zinc containing particles (e.g., zinc and/or zinc oxide) at high magnification using a Transmission Electron Microscope (“TEM”). FIG. 14A is magnified 10 times more than FIG. 14B and shows a closer view of the zinc oxide and silicon nitride particles coating a CNT. FIG. 14B is a TEM image of silicon nitride and zinc coated carbon nanotubes and a carbon nanotube protruding from a coating in the lower right corner. In embodiments, the pulse times, number of pulses, and purge times between pulses for DMZ and or water may vary depending on the desired properties of the resulting coated CNT (e.g., thickness of total coating, thickness or amount of zinc oxide in the resulting coating, etc.). In embodiments, the pulse times for the DMZ and/or water may be about 0.01 seconds or more, such as about 0.01 seconds to about 0.2 seconds, about 0.02 seconds to about 0.1 seconds, about 0.05 seconds to about 0.10 seconds, about 0.05 seconds to about 0.15 seconds, about 0.5 seconds, about 0.6 seconds, about 0.7 seconds. In embodiments, the number of pulses may be one or more pulses, such as about 1 pulse to about 10 pulses, about 2 pulses to about 8 pulses, about 3 pulses to about 7 pulses, about 3 pulses, about 4 pulses, 4 or more pulses, or about 5 pulses. In embodiments, the purge time between pulses may be about 1 second or more, such as about 1 second to about 1 minute, about 5 seconds to about 45 seconds, about 10 seconds to about 30 seconds, about 1 second to about 10 seconds, about 14 seconds, about 15 seconds, or about 16 seconds. In embodiments, any of the pulse times, number of pulses, and purge times may be different for each of DMZ and water respectively (i.e., water may have different parameters than DMZ), and combinations of any of the foregoing may be used, without limitation. In embodiments, diethyl zinc (DEZ) or another suitable zinc-containing precursor may be used in place of DMZ.

In embodiments, the CNT including the silicon nitride and zinc-containing material (e.g., zinc or ZnO) thereon may be further infiltrated or coated with one or more additional layers (e.g., a second layer) of silicon nitride in a LPCVD process similar or identical to that described above. The resulting TLC plate demonstrated some fluorescence, notably at the periphery of the TLC plate, however the fluorescence was severely muted. The inventors believe the fluorescence of the zinc oxide material was limited by a reaction of the zinc oxide with a byproduct—HCl—of the LPCVD deposition of silicon nitride. Thus, in embodiments, the zinc oxide material deposited on the silicon nitride material may be covered with a protective layer of silicon dioxide via ALD prior to deposition of a second portion of silicon nitride. For example, a thin film of silicon dioxide may be placed around the zinc oxide to protect it, by depositing the silicon dioxide using ALD using tris(dimethylamino)silane (“3DMAS”) and oxygen (O₂) plasma. The parameters used for silicon dioxide deposition may include a pulse time of 0.15 seconds, four times, with a purge time of 5 seconds for the 3DMAS; while the oxygen plasma may be made using oxygen flowed at about 20 sccm, 300 watts of pulse power and a 20 second pulse time, two times, with a 5 second purge time. In an embodiment, the 3DMAS pulse time may be about 0.05 seconds or more, such as about 0.05 seconds to about 0.5 seconds, about 0.05 seconds to about 0.25 seconds about 0.1 seconds to about 0.3 seconds, about 0.1 seconds to about 0.2 seconds, about 0.12 seconds to about 0.18 seconds, about 0.14 seconds, or about 0.16 seconds. The number of pulses may vary, for example, the 3DMAS may be pulsed 1 or more times, such as 1 to 10 pulses, 2 to 8 pulses, 3 to 6 pulses, 3 pulses, 4 or more pulses, or 5 pulses. The 3DMAS purge time may be about 1 second or more such as about 1 second to about 20 seconds, about 2 seconds to about 15 seconds, about 3 seconds to about 10 seconds, about 4 seconds, about 5 or more seconds, or about 6 seconds. In an embodiment, the oxygen plasma pulse time may be about 5 seconds or more, such as about 5 seconds to about 1 minute, about 10 seconds to about 45 seconds, about 15 seconds to about 30 seconds, about 19 seconds, about 20 seconds, or about 21 seconds. The oxygen gas flow may be about 5 sccm or more, such as about 5 sccm to about 25 sccm, about 10 sccm to about 30 sccm, about 15 sccm to about 25 sccm, about 10 sccm to about 50 sccm, about 18 to about 22 sccm, or about 20 sccm. The oxygen plasma pulse power may be about 200 watts or more such as about 100 watts to about 500 watts, about 20 watts to about 400 watts, about 250 watts to about 350 watts, about 275 watts, about 325 watts, or about 300 watts. The number of pulses may vary; for example, the oxygen plasma may be applied in 1 or more pulses, such as 1 to 5 pulses, 2 to 4 pulses, 1 to 3 pulses, 1 pulse, 2 or more pulses, or 3 pulses. The oxygen plasma purge time may be about 1 second or more such as about 1 second to about 20 seconds, about 2 seconds to about 15 seconds, about 3 seconds to about 10 seconds, about 4 seconds, about 5 seconds, or about 6 seconds. In embodiments, combinations of the any of the foregoing parameters may be used for ALD deposition of silicon dioxide, without limitation.

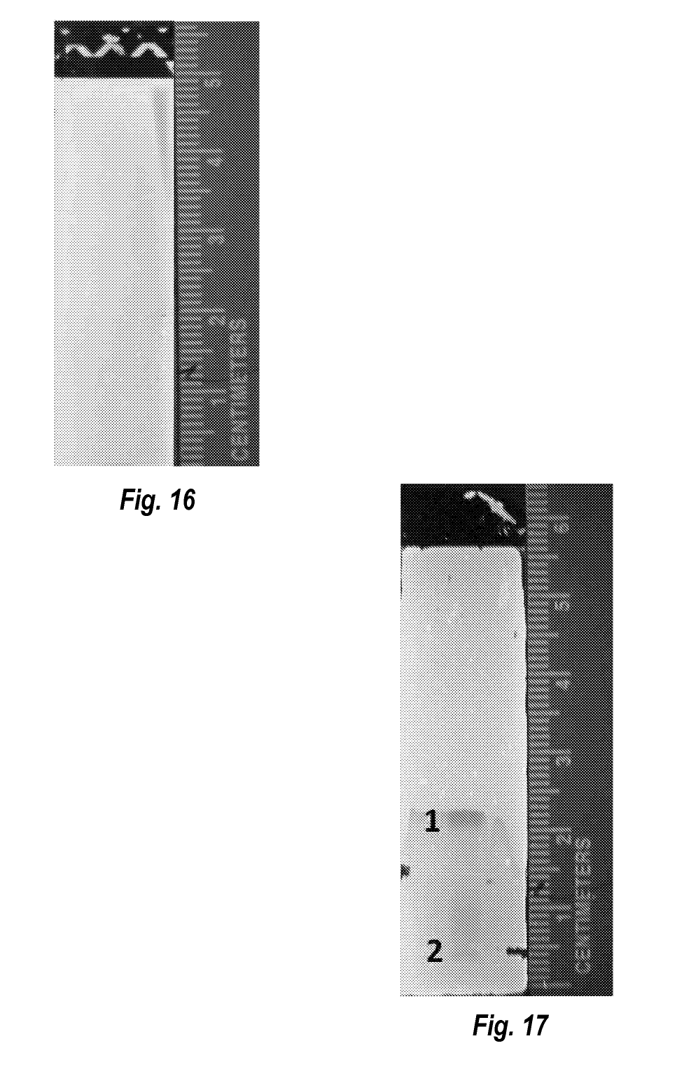

In embodiments, a second layer of silicon nitride may be applied to the CNT having silicon nitride, zinc or zinc oxide, and silicon dioxide thereon. The deposition of the second layer of silicon nitride may be accomplished using LPCVD using the parameters described above. In embodiments, the LPCVD of deposition of the second portion of silicon nitride may be accomplished using any of the parameters or combination of parameters described above for the first deposition of silicon nitride. The resulting coated CNT may be removed from the stationary phase structure by oxidation, for example, via heating the coated CNT to about 800° C. or more, such as about 800° C. to about 1200° C., about 900° C. to about 1100° C., about 950° C. to about 1050° C., about 950° C., about 1000° C., or about 1050° C. The silicon nitride present in the stationary phase structure may convert to silicon dioxide during the heating/oxidation process described above. The resulting TLC plates may be hydrated in aqueous ammonium hydroxide at about 50° C. for about two days. As demonstrated in FIGS. 16 and 17, after coating the silicon nitride, zinc oxide, and silicon dioxide protective layer, in a second layer of silicon nitride, and oxidizing the CNT the resulting TLC plate demonstrated excellent fluorescence under excitation from UV light (e.g., short wavelength UV light having a wavelength of, for example, about 254 nm).

In embodiments, a TLC plate may be formed by priming a CNT, having substantially no other material thereon, with ozone or a thin film of carbon (e.g., from amorphous carbon or graphite). The resulting CNT may exhibit an increased amount of oxygen moieties, or carbon moieties, respectively. The primed CNT may then be subjected to ZnO deposition by ALD in a substantially similar or identical manner as any described above for ZnO deposition by ALD. The ZnO and CNT may then be coated or infiltrated with silicon dioxide by ALD in a substantially similar or identical manner as any described above for silicon dioxide deposition by ALD. The CNT may be removed substantially as described above, the TLC plate may be hydrated substantially as described above, and the resulting TLC plate may exhibit fluorescence under UV light (e.g., short wavelength UV light, such as UV light having a wavelength of, for example, about 254 nm).

In an embodiment, a TLC plate may be formed in substantially the same manner as described immediately above, including priming the CNT, with the added act of deposition of a silicon nitride layer via LPCVD. The silicon nitride deposition may be performed in substantially any manner described herein for LPCVD of silicon nitride.

In an embodiment, a fluorescent material (e.g., ZnO) may be deposited on or attached to a primed CNT as a portion of a coating 108 or 108′. For example, in an embodiment, a CNT or plurality of CNTs may be oxidized with ozone or treated with a thin film of carbon (e.g., amorphous carbon or graphite) to prime the surface of the CNT in a substantially similar or identical manner as described above. The primed CNT may be directly coated with silicon nitride via ALD using DMZ or DEZ and water and/or oxygen or an oxygen plasma. Other zinc containing precursors may be used in this act, such as organozincs including methylzinc isopropoxide, methylzinc tert-butoxide, ethylzinc isopropoxide, or combinations thereof. Finally, the zinc oxide may be covered with a protective layer of silicon dioxide via ALD substantially as described above.

In an embodiment, fluorescent TLC plates may be formed by depositing or adhering zinc oxide onto a plurality of CNTs bonded to a backing substantially similar or identical to any described herein, wherein the deposition of ZnO is accomplished via plasma-enhanced chemical vapor deposition (“PECVD”). Subsequently, silicon nitride may be deposited on the CNT and zinc oxide via LPCVD in a substantially similar or identical manner as described above. Optionally, a protective coating of silicon dioxide may be applied to the zinc oxide material prior to deposition of the silicon nitride material. The deposition of silicon dioxide may be accomplished using any of the processes described herein for depositing silicon dioxide (e.g., ALD).

In embodiments, the zinc oxide deposited directly or indirectly on a CNT may be doped with another material, such as manganese, tin, strontium, or combinations thereof to achieve a desired fluorescence in the final stationary phase structure 108′. The doped zinc oxide may exhibit altered fluorescence such as change in color and/or intensity depending on the dopant.

After oxidation and/or removal of CNTs 106, in some embodiments, the TLC plate may be exposed to at least one acid (e.g., HF) or base (e.g., NH₄OH) to hydrate the stationary phase structures 108′. Where a base is used, the stationary phase may be immersed in the base etching solution at room temperature for a period of about 12 to about 72 hours (e.g., about 48 hours). Suitable bases include ammonium hydroxide, calcium hydroxide, sodium hydroxide, potassium hydroxides, other hydroxide salts, or combinations thereof. For example, TLC plates formed according to any of the above embodiments may be placed an aqueous ammonium hydroxide bath for a time sufficient to hydrate the stationary phase material thereon (e.g., 48 hours).

As another example, the TLC plate so formed (e.g., oxidized and removed CNTs) may be placed in a furnace in the presence of HCl or other acid (or base) so that HCl (or other) vapors result in placement of hydroxyl or silanol groups onto the surface of stationary phase structures 108′ to functionalize stationary phase structures 108′. Additional chemical functionality and selectivity may be added to the stationary phase structures 108′ by, for example, silanolization with alkyl moieties through any suitable gas phase chemistry as described in U.S. patent application Ser. No. 13/773,969, which was incorporated herein in its entirety above. Dip-coating methods may also be used to functionalize the stationary phase structures herein.

In an embodiment, the TLC plates may be produced with a concentration zone. This involves having an area that has relatively low retention where compounds may be spotted. This allows for the mobile phase to quickly pull the analyte through this area and then the analytes will slow down when they reach the normal sorbent bed. This can be done by making the pre-concentration area with a low density of the stationary phase structures and/or selectively functionalizing this area with a chemical species that allows for reduced retention of analytes.

In some embodiments, substrate 101 may be scribed or partially cut before or after growth of CNTs 106 and/or coating CNTs 106. By scribing or cutting substrate 101, smaller TLC plates may be fabricated by breaking a larger TLC plate along a scribe/cut line of substrate 101.

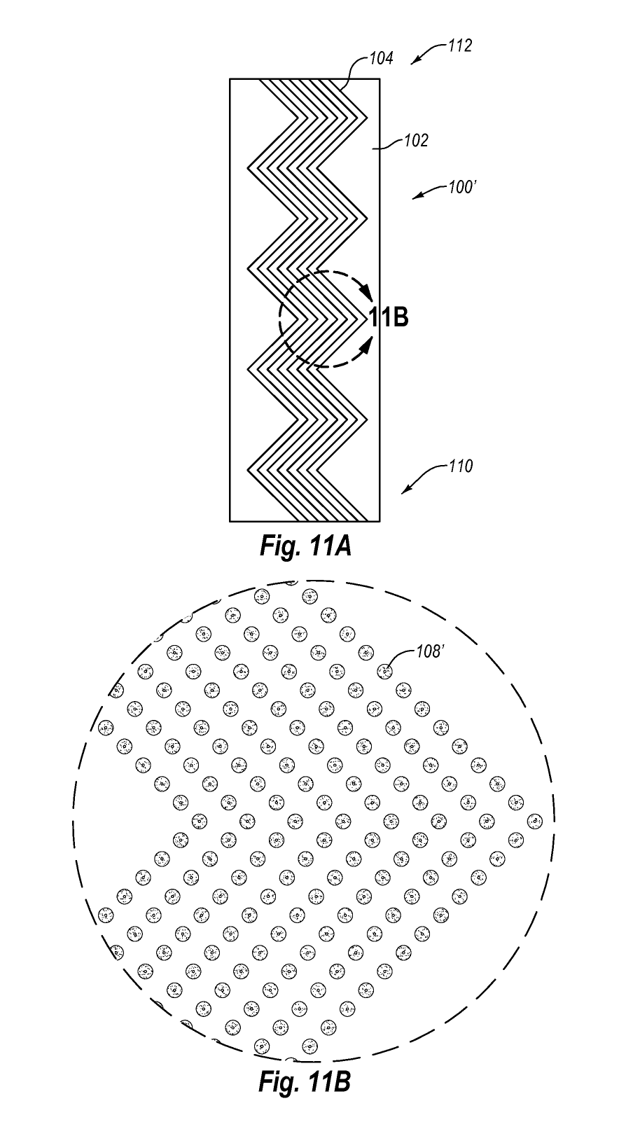

FIG. 11A is a top plan view of an embodiment of a TLC plate 100′. FIG. 11B is a close-up view of a portion of TLC plate 100′ includes stationary phase structures 108′ that are arranged between an end 110 and an end 112 of TLC plate 100′. TLC plates prepared according to the inventive methods disclosed herein provide a stationary phase in which the stationary phase is affixed to the substrate of the TLC plate without the use of any separate binding agent (e.g., calcium sulfate or a polymer). Such binding agents can interfere with the performance of the TLC plate as the result of secondary interactions resulting from the binding agent. The reduction or the elimination of any binding agent may result in a more high efficiency TLC plate, while minimizing and/or preventing such secondary interactions.

The spacing of the stationary phase structures 108′ is illustrated in FIGS. 11A and 11B as being generally uniform. However, in some embodiments, the density of the stationary phase structures 108′ may be different (e.g., greater or less) in different locations of the TLC plate 100′. For example, the density of the stationary phase structures 108′ may be different (e.g., greater or less) near end 110 than near end 112. Additional structures 108′ may fill the smaller space between adjacent structures 108′ in a given hedge so that each hedge is substantially continuous. Each hedge is separated from an adjacent hedge by a flow channel therebetween (e.g., as shown in FIG. 12). As an alternative to or in addition to the density of the stationary phase structures 108′ varying with location, the composition of the stationary phase structures 108′ may vary with location. As a non-limiting example, one portion of the stationary phase structures 108′ may comprise zirconium oxide and another portion of the stationary phase structures 108′ may comprise silica.

Furthermore, TLC plates prepared according to the methods disclosed herein provide a stationary phase having a particularly high porosity. The high porosity, as well as the absence of a binder may result in increased efficiency of the TLC plate during use in analyzing a sample within a mobile phase. In one embodiment, the TLC plates formed according to the disclosed methods are used to analyze a sample material. In an embodiment, the sample to be analyzed is applied to the stationary phase structures 108′ of TLC plate 100′ (e.g., near end 110). A mobile phase solvent or solvent mixture is then drawn along TLC plate 100′ (e.g., upwardly) by capillary action (e.g., by placing TLC plate 100′ in a container including the solvent or solvent mixture), or the mobile phase solvent or solvent mixture may be forced through TLC plate 100′. As the solvent or solvent mixture is drawn along the TLC plate 100′ via capillary action toward opposite end 112, the sample is dissolved in the mobile phase and separation of components within the sample is achieved because different components of the sample ascend the TLC plate 100′ at different rates. The high aspect ratio stationary phase structures 108′ as well as the bulk porosity as a result of the spacing between individual high aspect ratio stationary phase structures 108′ results in excellent separation efficiency of components within the sample as the sample components are carried through the stationary phase structures 108′ by the mobile phase (e.g., a solvent or solvent mixture). The TLC plates 100′ may also be used in HPTLC in which one or more of the method of use steps may be automated so as to increase the resolution achieved and to allow more accurate quantization.

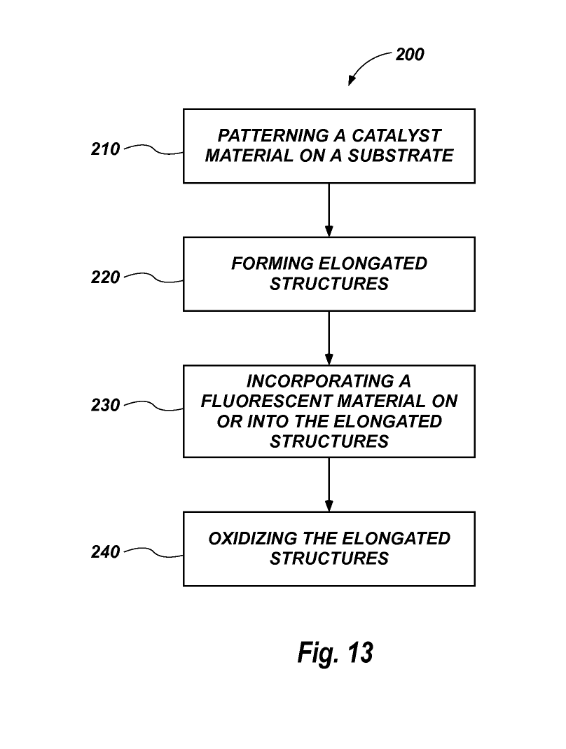

FIG. 13 depicts an embodiment of a method of making a photoluminescent TLC plate 200. In such an embodiment, a silicon base may be employed as a backing for a TLC plate. Act 210 includes patterning a catalyst material on a substrate. Patterning a catalyst material on a substrate may further include the act of applying (e.g., depositing or coating) a backing or barrier layer over the base to form a substrate, the backing layer may comprise alumina or any other suitable backing material described herein and may be applied by any method and in an amount or thickness described herein. Patterning a catalyst material on a substrate may include applying a catalyst material (e.g., iron) over the backing layer in any amount (e.g., thickness and/or pattern) and by any method described herein. Patterning a catalyst material on a substrate may include an act of coating the catalyst layer, including the underlying base and backing layer, with photoresist (e.g., AZ3312) in a substantially similar or identical manner (e.g., spin coating) as any described herein. Patterning a catalyst material on a substrate may include exposing the photoresist to pattern of light (e.g., UV light) to cause the exposed photoresist to be removed during development in a substantially similar or identical manner as any described herein. The base (e.g., silicon wafer, including the backing layer, catalyst layer, and photoresist thereon) may be immersed in or otherwise exposed to a developer (e.g., MIF-300) and the surface washed in deionized water or other stripping agent to expose the catalyst layer below the removed photoresist. Patterning a catalyst material on a substrate may include removing the exposed catalyst material (e.g., chemically etching) to define a pattern in the remaining masked catalyst material. Patterning a catalyst material on a substrate may include removing or lifting off (e.g., chemically dissolving or lifting) the photoresist from the catalyst and backing layers in substantially the same manner as any described herein for removing a photoresist layer. Act 220 includes forming (e.g., growing) elongated structures. In act 220, the elongated structures may be CNTs which may be grown or developed by flowing carbon-containing gas over the catalyst material as well as a process gas (e.g., under H₂ gas flow), under elevated temperature (e.g., 750° C.), in substantially the same manner as any described herein to grow CNTs. The resulting structure may resemble the structure depicted in FIG. 10B. Act 230 includes incorporating a fluorescent material or other photoluminescent material on or into (e.g., depositing onto or into) the elongated structures. In an act 230, a fluorescent material may be incorporated on or into the CNTs in a manner substantially similar or identical to any described herein, including but not limited to coating material(s) (e.g., silicon nitride, silicon dioxide, and zinc oxide), number of material layers and types of materials in layers, deposition techniques employed (e.g., LPCVD, ALD, and PECVD), particulate infiltration or adhering, and combinations of the foregoing. The resulting structure may resemble the structure depicted in FIG. 10D. The fluorescent material may be incorporated on or into the CNTs by at least partially coating the elongated carbon nanostructures with a coating including at least one of a stationary phase or a precursor of a stationary phase and at least one photoluminescent material. In a specific embodiment, a coating may include a first layer of silicon nitride deposited on the CNTs, a second layer of zinc oxide, a third protective layer of silicon dioxide, and a fourth outer layer of silicon nitride. For example, at least partially coating the CNTs may include depositing at least one photoluminescent material on the CNTs (e.g., such as in a layer on the outer surface of the CNT or at least partially infiltrated therein) and depositing at least one silicon-containing material on the CNTs having the at least one photoluminescent material thereon. In an embodiment, at least partially coating the CNTs may include depositing silicon nitride, such as in a layer, on the CNTs prior to depositing the at least one photoluminescent material. In an embodiment, depositing the photoluminescent material may include depositing a layer of zinc oxide on the silicon nitride deposited on the CNTs. For example, zinc oxide may be deposited on the CNTs via ALD using one of DMZ or DEZ and water as a set of ALD precursors as described herein. In an embodiment, depositing at least one additional silicon-containing material on the photoluminescent material on the CNTs may include depositing one or more of at least one layer of silicon dioxide or at least one layer of silicon nitride, such as a first layer of silicon dioxide and an additional layer of silicon nitride thereon.

Such coatings (e.g., applications of materials) may be carried out using one or more deposition techniques, such as LPCVD, ALD, and PECVD. For example, ALD can include flowing one or more materials over the elongated nanostructures substantially as described herein (e.g., in one or more pulses, with one or more purges therebetween, at one or more temperatures).

Act 240 includes oxidizing the elongated structures. In act 240, the coated CNT structure may be oxidized substantially as described herein (e.g., heating in an oxidizing atmosphere); the oxidation process may at least partially remove the CNT from within the coating, and may at least partially oxidize material(s) in the coating. The resulting structure may resemble the structure depicted in FIG. 10E. Subsequently, the coating may be hydrated using any of techniques described herein. The resulting TLC plate may include at least one fluorescent material and exhibit excellent fluorescent emission under UV light (e.g., short wavelength UV light). Variations of the foregoing are also considered herein.

### Working Examples

The following working examples are for illustrative purposes only and are not meant to be limiting with regards to the scope of the specification or the appended claims. Example 1 is representative of how the CNT structures were grown for all of the working examples, prior to coating.

### Example 1

Silicon wafers with a 4″ diameter, were used as the base for the substrate. The silicon wafer was coated by e-beam evaporation (Benton Vacuum E-beam Evaporator, Moorestown, N.J.) with a thin barrier layer of alumina (about 30 nm), and thermal evaporation (custom-built apparatus) with a few nanometers of iron (about 2-10 nm) over the alumina.

A mask for photolithography was used to form a pattern in the photoresist. A thin film of photoresist (about 1 μm), AZ-3312 (AZ Electronic Materials USA Corp, Somerville, N.J.), was spin coated onto the wafer. The resulting wafer was patterned via photolithography using UV light (Karl Suss Mask Aligner, Vermont, USA), immersed in a basic MIF-300 developer (AZ Electronic Materials USA Corp, Somerville, N.J.), washed in deionized water for two minutes and then dried. The exposed catalyst material was then removed by wet etching. The photoresist was then lifted off with an N-methylpyrollidone photoresist stripper, leaving a pattern of Al₂O₃/Fe at the surface.

The patterned wafer was loaded into a fused silica tube, and then heated to 750° C. in an atmosphere of hydrogen to reduce iron to its elemental form and substantially simultaneously produce iron nanoparticles. CNTs were grown at 750° C. with ethylene and hydrogen. The material was cooled under an atmosphere of argon to 200° C.

### Example 2

The CNTs of Example 1 were coated with silicon nitride using LPCVD. The precursors where ammonia and DCS. The ammonia was applied at 20 sccm and the DCS was applied at 80 sccm. The deposition temperature was about 780° C. Next, zinc oxide was deposited on the CNT and silicon nitride via ALD using DMZ and water as precursors. The ALD was accomplished using a Fiji F200 ALD system. Relatively high doses of precursor were used. Two sets of ALD parameters were individually successful for satisfactory zinc oxide deposition. The first set of parameters included DMZ and water pulse times of 0.06 seconds, four pulses, and a purge time of 15 seconds for each respective precursor. The second set of parameters included DMZ and water pulse times of 0.1 seconds and a purge time of 20 seconds respectively for each precursor.

A second thin film of silicon nitride was then deposited on the CNT including the zinc oxide material thereon via LPCVD substantially as described above. The TLC plate was oxidized in air at about 1000° C. to remove the CNTs and at least partially convert silicon nitride to silicon dioxide. The oxidized TLC plate was then hydrated in aqueous ammonium hydroxide at about 50° C. for about 48 hours. As demonstrated in FIG. 15B, the resulting TLC plate exhibited severely muted fluorescence under short wave UV light (e.g., 254 nanometers). The limited fluorescence is thought to be caused by reaction of the zinc oxide film with a byproduct—hydrochloric acid—of the LPCVD deposition of silicon nitride. By comparison, the TLC plate of FIG. 15A exhibited more fluorescence while still being muted, was made by depositing silicon nitride on a CNT, followed by zinc oxide. As demonstrated by FIG. 15B, the addition of a further layer of silicon nitride may severely limit fluorescence.

### Example 3

The CNTs on the TLC plate of example 1 were coated with a first portion or layer of silicon nitride and zinc oxide substantially as described above with respect to example 2. The zinc oxide material was then coated with a layer or portion of silicon dioxide via ALD using 3DMAS and an oxygen (O₂) plasma as precursors. The parameters for the ALD were a 3DMAS pulse time of 0.15 seconds for each of four pulses, with a purge time of 5 seconds; and oxygen flowed at 20 sccm to produce an oxygen plasma generated at 300 watts having a pulse time of 20 seconds for each of two pulses, and a purge time of 5 seconds.

A thin film (about 10 nm) of silicon nitride was then deposited on the silicon dioxide layer via ALD using similar parameters for silicon dioxide deposition by ALD to those described above. The TLC plate was oxidized in air at about 1000° C. to remove the CNTs and at least partially convert silicon nitride to silicon dioxide. The oxidized TLC plate was then hydrated in aqueous ammonium hydroxide at about 50° C. for about 48 hours. As demonstrated in FIGS. 16 and 17, the resulting TLC plate demonstrated excellent fluorescence under short wavelength (e.g., 254 nm) UV light, exhibiting a strong green color.

The TLC plate of example 3 was tested for separation characteristics using caffeine and amoxicillin as analytes. Both compounds were obtained from Sigma Aldrich (St. Louis, Mo.). A mixture of 1.5 mg/ml of each analyte was prepared in ethanol. The plates were spotted with 3 μl of the mixture using a Linomat V spotter (CAMAG, Muttenz, Switzerland). The bands were applied 5 mm from the bottom of the TLC plate and developed using 3 mL of chloroform:methanol:acetic acid in an 80:15:5 v/v/v mixture in a development chamber. As shown in FIG. 17, after development, the bands for each analyte could be seen under UV light (254 nm). No bands were present when no UV light was shined on the TLC plate.

While various aspects and embodiments have been disclosed herein, other aspects and embodiments are contemplated. The various aspects and embodiments disclosed herein are for purposes of illustration and are not intended to be limiting. Additionally, the words “including,” “having,” and variants thereof (e.g., “includes” and “has”) as used herein, including the claims, shall be open ended and have the same meaning as the word “comprising” and variants thereof (e.g., “comprise” and “comprises”).

What is claimed is:

1. A method of manufacturing a chromatography apparatus, the method comprising:
forming a catalyst layer on a substrate;
forming a layer of elongated nanostructures on the catalyst layer; and
incorporating at least one photoluminescent material with the elongated nanostructures including at least one of a stationary phase or a precursor of a stationary phase, wherein the act of incorporating includes:
depositing the at least one photoluminescent material on the elongated nanostructures; and
depositing at least one silicon-containing material on the elongated nanostructures having the at least one photoluminescent material thereon.

2. The method of claim 1 wherein the at least one photoluminescent material includes at least one fluorescent material.

3. The method of claim 2, wherein the at least one fluorescent material includes zinc oxide.

4. The method of claim 1, further comprising oxidizing the elongated nanostructures to remove at least a portion of the elongated nanostructures.

5. The method of claim 4, wherein oxidizing the elongated nanostructures to remove at least a portion of the elongated nanostructures includes heating the elongated nanostructures to about 800° C. or more in an oxidizing environment.

6. The method of claim 1, further comprising depositing silicon nitride on the elongated nanostructures prior to depositing the at least one photoluminescent material.

7. The method of claim 6, wherein incorporating at least one photoluminescent material with the elongated nanostructures includes at least partially coating the at least one photoluminescent material with silicon dioxide, and at least partially coating the elongated nanostructures with a second amount of silicon nitride.

8. The method of claim 7, wherein the silicon dioxide is deposited over the elongated nanostructures prior to at least partially coating the elongated nanostructures with the second amount of silicon nitride.

9. The method of claim 8, wherein:
depositing silicon nitride on the elongated nanostructures includes low-pressure chemical vapor deposition (“LPCVD”) using ammonia and dichlorosilane as a set of LPCVD precursors;
depositing at least one photoluminescent material includes depositing a layer of zinc oxide on the elongated nanostructures via atomic layer deposition (“ALD”) using dimethyl zinc (“DMZ”) and water as a set of ALD precursors; and
depositing at least one silicon-containing material on the elongated nanostructures having the at least one photoluminescent material thereon includes at least one of ALD of silicon dioxide or LPCVD of silicon nitride.

10. A method of manufacturing a chromatography apparatus, the method comprising:
depositing an alumina backing layer and an iron catalyst on a silicon base;
forming a layer of elongated carbon nanostructures on the iron catalyst by flowing a process gas and a carbon-containing gas thereacross;
at least partially coating the elongated carbon nanostructures with a coating including at least one of a stationary phase or a precursor of a stationary phase and at least one photoluminescent material, wherein the act of at least partially coating includes:
depositing silicon nitride on the elongated carbon nanostructures;
depositing zinc oxide on the silicon nitride on the elongated carbon nanostructures; and
depositing at least one additional silicon-containing material on the zinc oxide on the elongated carbon nanostructures; and
oxidizing the elongated carbon nanostructures to at least partially remove the elongated carbon nanostructures, leaving at least a portion of the silicon nitride, zinc oxide, and additional silicon-containing material as a stationary phase structure.

11. The method of claim 10, wherein at least partially coating the elongated carbon nanostructures includes at least partially coating the elongated carbon nanostructures having zinc oxide thereon with silicon dioxide and at least partially coating the elongated carbon nanostructures with a second amount of silicon nitride on the silicon dioxide coating.

12. The method of claim 10, wherein;
depositing silicon nitride on the elongated carbon nanostructures includes low-pressure chemical vapor deposition (“LPCVD”) using ammonia and dichlorosilane as a set of low LPCVD precursors;
depositing the zinc oxide on the silicon nitride on the elongated carbon nanostructures includes atomic layer deposition (“ALD”) using one of dimethyl zinc (“DMZ”) or diethyl zinc (“DEZ”) and water as a set of ALD precursors; and
depositing at least one additional silicon-containing material on the elongated carbon nanostructures includes at least one of ALD of silicon dioxide or LPCVD of silicon nitride.

13. The method of claim 12, wherein:
depositing silicon nitride with LPCVD of silicon nitride includes:
flowing ammonia over the elongated carbon nanostructures at about 60 sccm to about 100 sccm;
flowing dichlorosilane over the elongated carbon nanostructures at about 10 sccm to about 30 sccm; and
heating the elongated carbon nanostructures to a deposition temperature of about 700° C. to about 850° C.;
depositing zinc oxide with ALD includes a set of ALD parameters including one of:
pulsing the DMZ and water precursors over the elongated carbon nanostructures for about 0.01 seconds to about 0.2 seconds for each of four or more pulses, and a purge time of about 10 seconds to about 30 seconds, or
pulsing the DMZ and water precursors for about 0.05 seconds to about 0.15 seconds for one or more pulses and a purge time of about 10 seconds to about 30 seconds; and
deposition of silicon dioxide with ALD includes:
pulsing the 3DMAS precursor for about 0.05 seconds to about 0.25 seconds for each of four or more pulses with a purge time of about 3 seconds to about 10 seconds; and
pulsing the oxygen plasma precursor for a pulse power and time of about 250 watts to about 350 watts and about 10 seconds to about 30 seconds for each of two or more pulses with a purge time of about 3 seconds to about 10 seconds.

14. The method of claim 10, wherein oxidizing the elongated carbon nanostructures to at least partially remove the elongated carbon nanostructures, includes heating the coated elongated carbon nanostructures to about 800° C. or more in an oxidizing environment.

15. The method of claim 10, further comprising hydrating the chromatography apparatus having stationary phase structures thereon after oxidizing the elongated carbon nanostructures to at least partially remove the elongated carbon nanostructures leaving at least a portion of the silicon nitride, zinc oxide, or additional silicon-containing material as a stationary phase structure.

16. A chromatography apparatus, comprising:
a substrate;
a catalyst material on the substrate; and
a plurality of stationary phase structures formed over the substrate, at least some of the plurality of stationary phase structures including at least one photoluminescent material and at least one stationary phase or stationary phase precursor material including at least one of silicon dioxide or silicon nitride.

17. The chromatography apparatus of claim 16, wherein the at least one photoluminescent material includes at least one fluorescent material.

18. The chromatography apparatus of claim 17, wherein the at least one fluorescent material includes zinc oxide.

19. The chromatography apparatus of claim 16, wherein at least some of the plurality of stationary phase structures includes a layered conformation including an inner layer of silicon nitride, the inner layer coated by a layer of zinc oxide, the layer of zinc oxide coated by a protective layer of silicon dioxide, and the protective layer coated with an outer layer of silicon nitride.

20. The chromatography apparatus of claim 16, wherein at least some of the plurality of stationary phase structures includes a portion of a carbon nanotube therein.

21. The chromatography apparatus of claim 16 wherein at least some of the plurality of stationary phase structures include a layered conformation including an inner layer of silicon nitride, the inner layer coated by a layer of zinc oxide, the layer of zinc oxide coated by a protective layer of silicon dioxide, and the protective layer coated with an outer layer of silicon nitride that is at least partially oxidized to contain silicon dioxide.

22. The chromatography apparatus of claim 16, wherein the plurality of stationary phase structures include elongated nano-scale structures or elongated carbon nanotubes.
